(19) United States
(12) Patent Application Publication
(10) Pub. No.: US 2026/0259382 A1
(43) Pub. Date: Sep. 3, 2026

(54) COMPONENT WITH PHOTONIC INTEGRATED CIRCUIT

(71) Applicant: ams-OSRAM International GmbH, Regensburg (DE)

(72) Inventor: Farhang GHASEMI AFSHAR, Wenzenbach (DE)

(21) Appl. No.: 18/863,658

(22) PCT Filed: May 4, 2023
(86) PCT No.: PCT/EP2023/061778

§ 371 Date: Nov. 7, 2024

(30) Foreign Application Priority Data
May 12, 2022 (DE) 10 2022 111 949.1

(51) Int. Cl. G02B 6/42; G02B 6/43

(52) U.S. Cl. CPC G02B 6/4274; G02B 6/4202; G02B 6/425; G02B 6/4259; G02B 6/4295; G02B 6/43

(57) ABSTRACT

A component with photonic integrated circuit comprises an input terminal having a first input contact and a second input contact for applying an input voltage between the first input contact and the second input contact. The component further comprises an optical voltage converter for providing an output voltage at an internal output terminal of the component for operating the photonic integrated circuit. The optical voltage converter is configured such that the output voltage provided by the optical voltage converter is higher than the input voltage.

### CROSS-REFERENCE TO RELATED APPLICATIONS

This application is a national phase of PCT/EP2023/061778 filed on May 4, 2023, which claims priority to German Application No. 102022111949.1, which was filed on May 12, 2022, the entire contents of both of which are incorporated herein by reference.

### TECHNICAL FIELD

The following disclosure relates to a component with a photonic integrated circuit that is controlled or operated with a control voltage.

### BACKGROUND

Conventional integrated circuits are based on the conduction of electric current, i.e. the flow of free electrons through the circuit, while photonic integrated circuits (PICs) use photons, i.e. massless elementary particles, instead of electrons. Photons move through the transmission medium at the speed of light and therefore with virtually no interference from other photons. This means that the bandwidth and transmission speed of a circuit can be significantly increased, while the energy loss is reduced.

Photonic integrated circuits that use electro-optical effects for active elements, such as modulators, usually have to be supplied with control or operating voltages that are significantly higher than the supply voltages used in modern electrical circuits. Electrical circuits, for example, are often supplied with low voltages of 3.3 V or with voltage levels that are even below 3.3 V.

Photonic integrated circuits, on the other hand, require significantly higher voltages for their operation or control, for example voltages in the range of 20 V or higher. Generating such a high control/operating voltage using an electronic circuit and then applying it externally to the photonic integrated circuit involves a great deal of effort and space.

In the following, therefore, a component with a photonic integrated circuit is to be specified, in which an operating or control voltage for operating or controlling the photonic integrated circuit can be provided in an effective manner.

### SUMMARY

A component with a photonic integrated circuit in which an operating or control voltage is provided to operate or control the photonic integrated circuit without the need to provide a dedicated external electronic circuit that generates a high operating/control voltage that must be externally applied to the photonic integrated circuit is specified in claim 1.

Accordingly, a component with a photonic integrated circuit comprises an input terminal having a first input contact and a second input contact for applying an input voltage between the first input contact and the second input contact. Furthermore, the component comprises an optical voltage converter for providing an output voltage at an internal output terminal of the component for operating the photonic integrated circuit. The optical voltage converter is configured such that the output voltage provided by the optical voltage converter is higher than the input voltage.

The basic idea is to provide a component in which an optical voltage converter for generating a voltage for operating, supplying or controlling a photonic integrated circuit is integrated into the component together with the photonic integrated circuit. This means that the optical voltage converter and the photonic integrated circuit are arranged in a housing of the component.

While only a low input voltage is applied to the component from the outside, for example a voltage with a level of 3.3 V or less, which is common in electrical circuits, the optical voltage converter integrated into the component generates the high supply/operating/control voltage for the photonic integrated circuit. By generating the voltage required for the opto-electrical effects of the photonic integrated circuit within the component, the housing and an electrical circuit board, on which the operating or control voltage for the photonic integrated circuit would otherwise have to be generated, can be significantly simplified. Instead, only the supply voltage required to operate the electrical components, which is significantly lower than the operating or control voltage for the photonic integrated circuit, is generated on the electrical circuit board.

According to a possible embodiment, the component comprises a carrier substrate. The optical voltage converter comprises at least one light-emitting diode for generating light and at least one photovoltaic chip and/or at least one further light-emitting diode for converting the light generated by the at least one light-emitting diode into the output voltage. The at least one light-emitting diode for generating light and the at least one photovoltaic chip and/or the at least one further light-emitting diode for converting the generated light into the output voltage for operating or controlling the photonic integrated circuit are arranged on the carrier substrate. Micro-LEDs (μ-LEDs) or mini-LEDs (m-LEDs) can be provided as light-emitting diodes for generating light and light-emitting diodes for converting the generated light into the output voltage.

As a broad definition, a micro LED could be seen as any light emitting diode (engl. “light-emitting diode” abbreviated to “LED”)—generally not a laser—with a particularly small size.

As a rule—and in addition to size, this is also a very important criterion—micro-LEDs have a wax-up substrate removed, so that typical heights of such micro-LEDs are in the range of 1.5 μm to 10 μm, for example.

In principle, a micro-LED does not necessarily have to have a rectangular radiation emission surface. In general, for example, an LED with a radiation emitting surface in which each lateral extension of the radiation emitting surface is less than or equal to 100 μm or less than or equal to 70 μm when viewed from above on the layers of the layer stack could be used.

For example, an edge length of less than or equal to 70 μm or less than or equal to 50 μm is often mentioned as a criterion for rectangular micro-LEDs—especially when viewed from above on the layers of the layer stack.

In most cases, such micro-LEDs are provided on wafers with non-destructive holding structures for the μLED.

Micro-LEDs are currently primarily used in displays. The micro-LEDs form pixels or sub-pixels and emit light of a defined color. Due to the small pixel size and high density with a small distance, micro LEDs are suitable for small monolithic displays for AR applications, in particular data glasses. Work is also being carried out on other applications, in particular in data communication or pixelated lighting applications.

Various spellings for micro LED can be found in the literature, e.g. μLED, μ-LED, uLED, u-LED or Micro Light Emitting Diode.

According to a possible embodiment of the component with photonic integrated circuit, the optical voltage converter comprises a plurality of the at least one light-emitting diode for generating light and a plurality of the at least one photovoltaic chip and/or a plurality of the at least one further light-emitting diode for converting the generated light into the output voltage. The plurality of the light-emitting diodes for generating light are connected in parallel between the first input contact and the second input contact. The plurality of photovoltaic chips and/or the plurality of further light-emitting diodes for converting the generated light into the output voltage for operating or controlling the photonic integrated circuit are arranged in a series circuit between a first internal output contact and a second internal output contact of the internal output terminal for generating the output voltage.

In the above embodiment, the optical voltage converter thus comprises several light-emitting diodes which are connected in parallel between the first input contact and the second input contact of the input terminal for applying the input voltage in order to generate light. These light-emitting diodes are used to generate light. The photovoltaic chips or further light-emitting diodes connected in series between the first internal output contact and the second internal output contact are used to generate voltage by converting the light generated by the light-emitting diodes connected in parallel, i.e. an optical signal, into an electrical output voltage, i.e. an electrical signal.

With the proposed arrangement of parallel-connected light-emitting diodes for light generation and series-connected photovoltaic chips and/or further light-emitting diodes for voltage generation, voltage levels can be generated that are significantly higher than the supply voltage levels used in integrated circuits, for example voltage levels of 3.3 V or less. In particular, supply/operating or control voltages of more than 20 V can thus be generated to operate or control a photonic integrated circuit without the need to connect a dedicated external voltage source to the input terminal of the component to generate the high voltages.

In the proposed concept, however, the level of the input voltage applied to the input terminal remains at a low voltage level, for example the forward voltage of a single light-emitting diode, in particular m-LED, while the voltage provided at the internal output terminal by the optical voltage converter is raised to a higher voltage level depending on the number of photovoltaic chips and/or further light-emitting diodes connected in series.

According to a possible embodiment of the component with photonic integrated circuit, the optical voltage converter comprises a reflective layer which is arranged above the at least one light-emitting diode and the at least one photovoltaic chip and/or the at least one further light-emitting diode. In addition, the optical voltage converter has an intermediate layer made of a light-transparent material. The intermediate layer is arranged between the substrate of the optical voltage converter and the reflective layer.

The light emitted by the at least one light-emitting diode to generate light first passes through the light-transparent material of the intermediate layer and is reflected back at the reflective layer onto the at least one photovoltaic chip and/or onto the at least one further light-emitting diode. The reflected light is converted by the at least one photovoltaic chip and/or the at least one light-emitting diode into the output voltage for application to the photonic integrated circuit.

According to a further possible embodiment of the component with photonic integrated circuit, the intermediate layer may comprise wavelength-converting particles which are mixed into the light-transparent material of the intermediate layer. In particular, if the received spectrum of the at least one photovoltaic chip and/or the at least one further light-emitting diode for converting the generated light into the output voltage differs in wide spectral ranges from the wavelength spectrum generated by the light-emitting diode for generating light, wavelength-converting particles can be arranged in the intermediate layer, which adapt the generated light spectrum to the wavelength-specific sensitivity or sensitiveness of the at least one photovoltaic chip and/or the at least one further light-emitting diode.

For example, if the optical voltage converter comprises blue LEDs for light generation and commercial photovoltaic chips are provided for converting the generated light into the output voltage, a white down converter, for example a phosphor, can be added to the matrix material of the intermediate layer in order to adapt the generated light spectrum to the light wavelength-specific reception spectrum of the photovoltaic chips.

According to a further possible embodiment of the component with photonic integrated circuit, the plurality of light emitting diodes may be arranged on a first region of the carrier substrate. The plurality of photovoltaic chips and/or the plurality of further light emitting diodes for converting the generated light into the output voltage may be arranged on a second region of the carrier substrate, which is different from the first region of the substrate.

With the proposed concept, different output voltage levels can be provided depending on the light intensity with which the light-emitting diodes in the first area of the carrier substrate generate the light. At low intensities of the generated light, for example, only the photovoltaic chips or further light-emitting diodes arranged close to the first area receive the emitted light and contribute to the generation of the output voltage. If, on the other hand, the light is generated with high intensity by the light-emitting diodes in the first area of the carrier substrate, significantly more photovoltaic chips or further light-emitting diodes in the second area of the carrier substrate receive the generated light, so that a higher level of output voltage can be generated.

According to a possible embodiment of the component with photonic integrated circuit, the optical voltage converter comprises at least one optical waveguide which is arranged between the at least one light-emitting diode and the at least one photovoltaic chip and/or the at least one further light-emitting diode for converting the generated light into the output voltage. In this embodiment, the light generated by the at least one light-emitting diode can be guided specifically through an optical waveguide provided for this purpose to the at least one photovoltaic chip and/or to the at least one further light-emitting diode at the other end of the optical waveguide in order to generate the output voltage.

According to another embodiment of the component with photonic integrated circuit, the optical voltage converter comprises a light-transparent intermediate substrate which is arranged between the at least one light-emitting diode for generating light and the at least one photovoltaic chip and/or the at least one further light-emitting diode for converting the generated light into the output voltage. In this embodiment, the light-transparent intermediate substrate serves both as a carrier substrate for arranging the at least one photovoltaic chip and/or the at least one further light-emitting diode for converting the generated light into the output voltage and for distributing light between the at least one light-emitting diode for generating light and the at least one photovoltaic chip and/or the at least one further light-emitting diode.

According to a further possible embodiment of the component with photonic integrated chip, the optical voltage converter may comprise a substrate on which the plurality of light-emitting diodes for generating light are arranged. Furthermore, the optical voltage converter may comprise a second substrate on which the plurality of photovoltaic chips and/or the plurality of further light-emitting diodes are arranged. The substrate on which the plurality of light-emitting diodes for generating light are arranged may be formed as a thin-film substrate. According to a possible embodiment, the plurality of photovoltaic chips and/or the plurality of further light-emitting diodes for converting the generated light into the output voltage can be arranged directly on the plurality of light-emitting diodes for generating light. This makes it possible to produce a very compact component with a low component height.

According to another possible embodiment of the component with a photonic integrated chip, the optical voltage converter also comprises a substrate on which the plurality of light-emitting diodes for generating light are arranged, and a second substrate on which the plurality of photovoltaic chips and/or the plurality of further light-emitting diodes for converting the generated light into the output voltage are arranged. The substrate can be formed as a thin-film substrate. The optical voltage converter can comprise a light-transparent intermediate substrate, which is arranged between the plurality of light-emitting diodes for generating light and the plurality of photovoltaic chips and/or the plurality of further light-emitting diodes for converting light into the output voltage. In this embodiment, the light-transparent intermediate substrate serves to distribute the generated light to the plurality of photovoltaic chips and/or the plurality of further light-emitting diodes.

According to a further embodiment of the component with a photonic integrated chip, the optical voltage converter comprises a substrate on which the plurality of light-emitting diodes for generating light are arranged. The substrate can be formed as a thin-film substrate. Furthermore, the optical voltage converter comprises a light-transparent intermediate substrate, which is arranged between the plurality of light-emitting diodes and the plurality of photovoltaic chips and/or the plurality of further light-emitting diodes. In this embodiment, the light-transparent intermediate substrate serves both as a carrier substrate for the plurality of photovoltaic chips and/or the plurality of further light-emitting diodes for converting the generated light into the output voltage and for distributing the light generated by the light-emitting diodes on the thin-film substrate. A second substrate as a carrier for the photovoltaic chips and/or further light-emitting diodes can thus be dispensed with.

According to a possible embodiment, the component with photonic integrated chip comprises a control terminal for applying a control signal. The optical voltage converter comprises a control circuit. The control circuit is configured to provide different levels of the output voltage at the internal output terminal depending on the control signal applied. As a result, the level of the output voltage generated by the optical voltage converter can be varied by applying an external control signal to the component.

According to a further possible embodiment, the component with photonic integrated circuit comprises a plurality of the optical voltage converter and at least one control logic circuit. The control logic circuit is configured to select at least one of the plurality of optical voltage converters to generate the output voltage. In the proposed embodiment, it is thus possible to vary the level of the output voltage by selecting one or more voltage converters for generating the output voltage by the control logic circuit.

According to a possible embodiment of the component with photonic integrated chip, components of the photonic integrated circuit can be arranged on the carrier substrate of the component. According to this embodiment, a single substrate can thus be used, for example, as a carrier substrate for the components of the optical voltage converter, in particular for the light-emitting diodes for generating light and for the photovoltaic chips and/or the further light-emitting diodes for generating the output voltage, and also as a carrier substrate for the components of the photonic integrated circuit.

According to a further embodiment of the component with photonic integrated circuit, the component can comprise a second carrier substrate on which components of the photonic integrated circuit are arranged. In this embodiment, the second carrier substrate is arranged in the housing of the component spatially separated from the carrier substrate on which the components of the optical voltage converter are provided.

In this embodiment, the photonic integrated circuit may comprise an internal input terminal for applying the output voltage of the optical voltage converter. The internal output terminal of the optical voltage converter and the internal input terminal of the photonic integrated circuit may be connected to each other via a bonding wire.

According to another embodiment of the component with separate carrier substrates for the optical voltage converter and the photonic integrated circuit, the carrier substrate for the optical voltage converter and the second carrier substrate for the photonic integrated circuit can be accommodated in the housing in a stacked arrangement.

### BRIEF DESCRIPTION OF THE DRAWINGS

Embodiments of the component with photonic integrated circuit are described below by figures.

FIG. 1 an embodiment of a component with a photonic integrated circuit and an optical voltage converter,

FIG. 2 a cross-section of an embodiment of an optical voltage converter for providing an output voltage for operating a photonic integrated circuit,

FIG. 3 a cross-section of an embodiment of an optical voltage converter with a light-transparent intermediate layer between a carrier substrate and a reflective layer,

FIG. 4 an embodiment of an optical voltage converter with wavelength-converting particles in a light-transparent intermediate layer between a carrier substrate and a reflective layer,

FIG. 5 an embodiment of an optical voltage converter with light-emitting diodes for generating light and photovoltaic chips/further light-emitting diodes for converting the generated light into an output voltage arranged in different areas of a carrier substrate,

FIG. 6A a cross-section of an embodiment of an optical voltage converter with optical waveguides between light-emitting diodes for generating light and light-emitting diodes for converting the light into an output voltage,

FIG. 6B a top view on an embodiment of an optical voltage converter with optical waveguides between light-emitting diodes for generating light and light-emitting diodes for converting the generated light into an output voltage,

FIG. 7A a cross-section of an embodiment of an optical voltage converter with a light-transparent intermediate substrate between light-emitting diodes for generating light and photovoltaic chips/further light-emitting diodes for converting the generated light into an output voltage,

FIG. 7B a top view on an embodiment of an optical voltage converter with a light-transparent intermediate substrate between light-emitting diodes for generating light and photovoltaic chips/light-emitting diodes for converting the generated light into an output voltage,

FIG. 8A light-emitting diodes for light generation in an arrangement on a thin-film substrate,

FIG. 8B photovoltaic chips/light-emitting diodes in an arrangement on a substrate,

FIG. 8C an embodiment of an optical voltage converter with photovoltaic chips/light-emitting diodes for generating an output voltage arranged directly on light-emitting diodes for light generation,

FIG. 8D an embodiment of an optical voltage converter with a light-transparent intermediate substrate between light-emitting diodes for generating light and photovoltaic chips/light-emitting diodes for converting the generated light into an output voltage,

FIG. 8E an embodiment of an optical voltage converter with a light-transparent intermediate substrate as a carrier for photovoltaic chips/light-emitting diodes for voltage generation,

FIG. 9 an embodiment of an arrangement for generating an output voltage with a plurality of optical voltage converters and at least one control logic circuit for selecting the optical voltage converters for generating the output voltage,

FIG. 10 an embodiment of a component with an optical voltage converter and a photonic integrated circuit on separate carrier substrates,

FIG. 11A a top view on an optical voltage converter and a photonic integrated circuit with spatially separated carrier substrates,

FIG. 11B a component with a photonic integrated circuit and an optical voltage converter with spatially separated carrier substrates in a stacked arrangement,

FIG. 12 an embodiment of an optical voltage converter with a control circuit for generating levels of an output voltage.

### DETAILED DESCRIPTION

In the embodiment examples and figures, identical, similar or similarly acting elements may be provided with the same reference signs. The elements shown and their relative sizes are not to be regarded as true to scale; rather, individual elements, such as components, structural elements and areas, may be shown in exaggerated size for better visualization and/or better understanding.

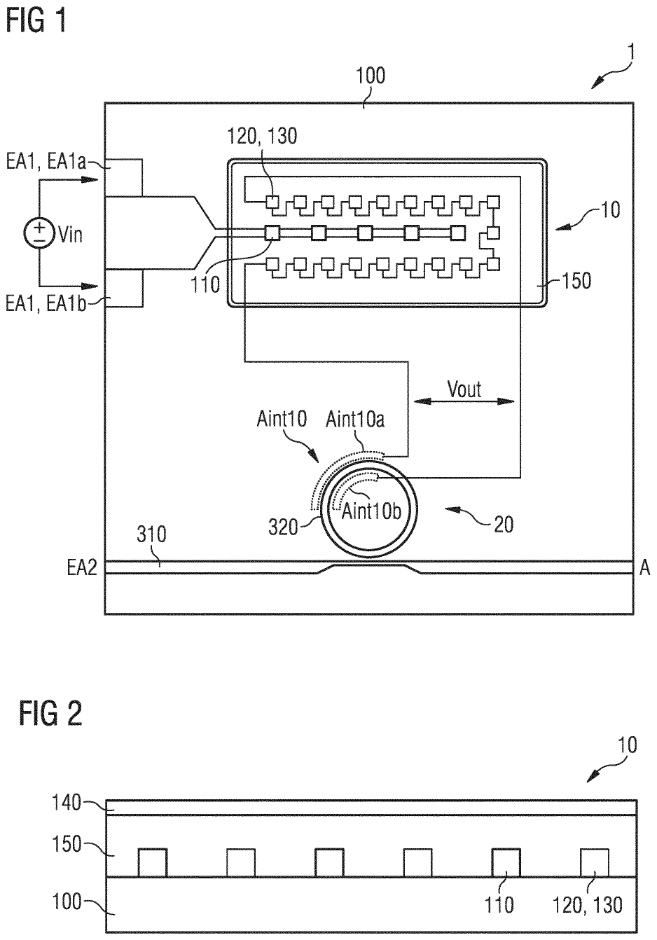

An embodiment of a component 1 with a photonic integrated circuit 20 and an optical voltage converter 10 for providing an output voltage Vout for operating the photonic integrated circuit, wherein the optical voltage converter 10 and the photonic integrated circuit 20 are integrated in the component 1, is shown in FIG. 1. The optical voltage converter 10 and the photonic integrated circuit 20 are arranged in a housing 30 of the component 1.

The component 1 has an input terminal EA1 with a first input contact EA1a and a second input contact EA1b for applying an input voltage Vin between the first input contact EA1a and the second input contact EA1b. To operate the photonic integrated circuit 20, the optical voltage converter 10 provides an output voltage Vout at an internal output terminal Aint10 of the component 1. The optical voltage converter 10 is configured such that the output voltage Vout provided by the optical voltage converter 10 is higher than the input voltage Vin.

The proposed concept of a component 1 with a photonic integrated circuit, in which an optical voltage converter 10 is integrated, enables the internal generation of high voltage levels for the output voltage Vout in the component 1. It is therefore not necessary to generate high voltage levels, which are required to operate or control the photonic integrated circuit 20, on an electronic circuit board by means of a voltage generator provided specifically for this purpose. Instead, only an input voltage with a low voltage level is present at the input terminal EA1. This input voltage can be generated by a voltage generator on an electronic circuit board. This voltage generator can be a circuit that is already present on the electrical circuit board to generate supply voltages for electrical components, for example voltage levels of less than or equal to 3.5 volts. The component 1 therefore does not require an external connection to apply high voltage levels, which would otherwise have to be generated externally specifically to operate or control the photonic integrated circuit. This increases the added value of the component.

By generating the output voltage Vout for operating or controlling the photonic integrated circuit 20 within the housing 30, the space required to generate the voltage for operating the photonic integrated circuit can be reduced, as no external electronic circuit specifically provided for this purpose is required. In particular, the internal output terminal Aint10 of the optical voltage converter 10 for providing the output voltage Vout for operating the optically integrated circuit 20 can be made significantly smaller than if the high voltage levels for operating or controlling the photonic integrated circuit were applied externally to the component 1.

The optical voltage converter 10 has at least one light-emitting diode 110 for generating light and at least one photovoltaic chip 120 and/or at least one further light-emitting diode 130 for converting the light generated by the at least one light-emitting diode 110 into the output voltage Vout. According to a possible embodiment, the light-emitting diodes 110 and 130 can be embodied as micro-LEDs (μ-LEDs) or mini-LEDs (m-LEDs). This allows the component 1 to be very compact in size. Since u-LEDs or m-LEDs are very fast electronic components, the components of the photonic integrated circuit can be operated or controlled at high frequency. The component 1 has a carrier substrate 100 on which the at least one light-emitting diode 110 and the at least one photovoltaic chip 120 and/or the at least one further light-emitting diode 130 are arranged.

In the embodiment of the component 1 with photonic integrated circuit 20 shown in FIG. 1, the optical voltage converter 10 has a plurality of light-emitting diodes 110 for generating light. Furthermore, the optical voltage converter 10 comprises a plurality of photovoltaic chips 120 and/or a plurality of further light-emitting diodes 130 for converting the generated light into the output voltage Vout. The plurality of light-emitting diodes 110 for generating light are connected in parallel between the first input contact EA1a and the second input contact EA1b. The plurality of photovoltaic chips 120 and/or the plurality of further light-emitting diodes 130 are arranged in a series circuit between a first internal output contact Aint10a and a second internal output contact Aint10b of the internal output terminal Aint10.

By adjusting the current flowing through the LEDs 110 connected in parallel, a desired level of the output voltage Vout or a desired level of an output current can be easily generated. By changing the current through the light emitting diodes 110, the output voltage Vout can be modulated. In particular, the photovoltaic chips 120 or further light-emitting diodes 130 can be arranged in parallel in groups within the series circuit in order to achieve the desired level of the output voltage Vout.

For example, the photonic integrated circuit 20 may comprise an optical waveguide 310 and a ring oscillator 320. When a broadband light of a laser is coupled to an input terminal EA2 of the component 1, narrowband light can be generated by the ring oscillator 320 at an output terminal A as a function of the level of the output voltage Vout.

FIG. 2 shows a cross-section of a possible embodiment of the optical voltage converter 10. The light-emitting diodes 110 for generating light as well as the photovoltaic chips 120 and/or the further light-emitting diodes 130 for converting the light generated by the light-emitting diodes 110 into the output voltage Vout are arranged on a carrier substrate 100. The optical voltage converter 10 further comprises a reflective layer 140 arranged over the light emitting diodes 110 and the photovoltaic chips 120 and/or the further light emitting diodes 130. Furthermore, the optical voltage converter 10 comprises an intermediate layer 150 made of a light-transparent material. The intermediate layer 150 is arranged between the carrier substrate 100 and the reflective layer 140.

The light emitted by the light-emitting diodes 110 is radiated through the light-transparent material of the intermediate layer 150, inter alia, in the direction of the reflective layer 140. The light is reflected by the reflective layer 140 back onto the photovoltaic chips 120 and/or the further light-emitting diodes 130. The reflected light is converted into the output voltage Vout by the photovoltaic chips 120 and/or the further light-emitting diodes 130. The reflective layer 140 can be formed as an opaque layer and thus prevents light from penetrating out of the optical voltage converter 10 or being coupled into the photonic integrated circuit. In addition, the efficiency in generating the output voltage is increased by an opaque material for the reflective layer 140, in that the light emitted upwards by the light-emitting diodes 110 is reflected back to the photovoltaic chips 120 and/or the further light-emitting diodes 130 and is therefore converted into the output voltage Vout.

The intermediate layer 150 may comprise wavelength-converting particles 160 that are mixed into the light-transparent material of the intermediate layer 150. The wavelength-converting particles 160 may, for example, be down-converting particles, in particular phosphors, by means of which the wavelength of the light emitted by the light-emitting diodes 110 can be adapted to the wavelength-specific sensitivity of the photovoltaic chips 120 and/or the further light-emitting diodes 130.

If no adjustment of the wavelength spectrum is required, the wavelength-converting particles 160 can be dispensed with within the intermediate layer 150. This is possible, for example, if the same light-emitting diodes are used to generate the light that are also used to convert the generated light into the output voltage Vout.

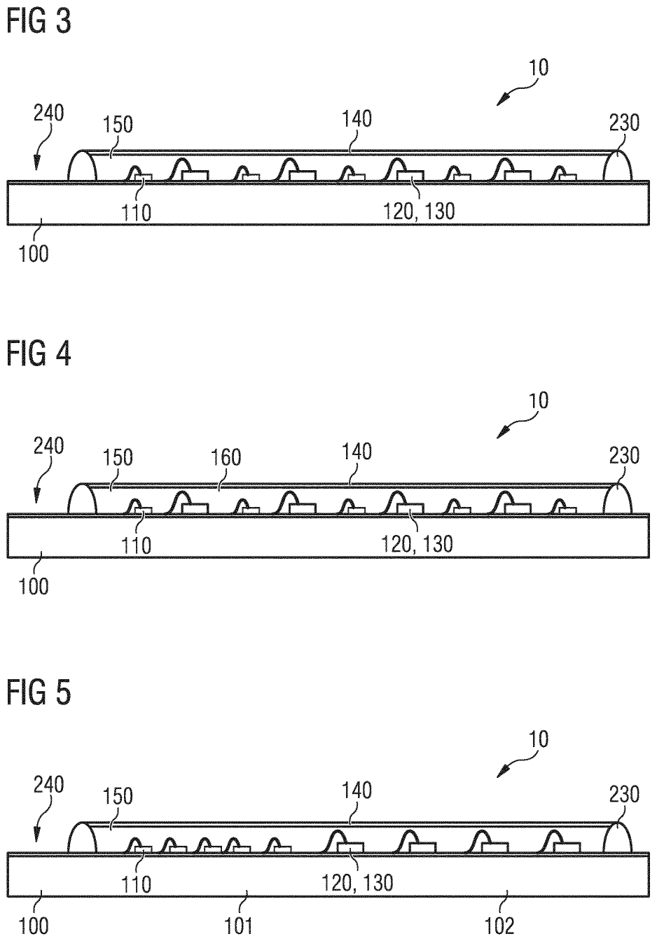

FIG. 3 shows a cross-section of a possible embodiment of the optical voltage converter 10, in which light-emitting diodes 110 for generating light and photovoltaic chips 120 and/or further light-emitting diodes 130 as voltage generators for generating the output voltage Vout are arranged alternately on the carrier substrate 100. The reflective layer 140 is arranged above the light-emitting diodes 110 and the photovoltaic chips 120 and/or the further light-emitting diodes 130 at a distance which is predetermined by the height of a dam 230. The light-emitting diodes 110 and the photovoltaic chips 120 or further light-emitting diodes 130 can be arranged on a metallization 240, which is provided on the carrier substrate 100.

The dam 230 may be formed from a material of silicone, a thermoplastic material or a ceramic material. Furthermore, the dam 230 can be provided as a metallic frame.

The reflective layer 140 can be formed as a metallic plate or as a highly reflective ceramic. Furthermore, a material made of silicone into which particles of titanium dioxide are mixed can be used for the reflective layer 140.

An intermediate layer 150 made of a light-transparent material is arranged between the carrier substrate 100 and the reflective layer 140. The light-transparent material of the intermediate layer 150 can, for example, be a material made of silicone or a material made of silicone in which light-refracting particles are mixed. As a result, the light emitted by the light-emitting diodes 110 is scattered in the intermediate layer 150.

FIG. 4 shows a further embodiment of the optical voltage converter 10. In contrast to the embodiment shown in FIG. 3, the intermediate layer 150 between the carrier substrate 100 and the reflective layer 140 comprises wavelength-converting particles 160, which are mixed into the light-transparent material of the intermediate layer 150. The wavelength-converting particles 160 allow the spectrum of the light emitted by the light-emitting diodes 110 to be adapted to the reception spectrum of the photovoltaic chips 120 or the other light-emitting diodes 130.

For example, phosphors can be used as wavelength-converting particles, which are added to the matrix material of the intermediate layer 150 in order to change the wavelength of the light emitted by the light-emitting diodes 110 and thus adapt it to the wavelength-specific sensitivity of the photovoltaic chips 120 and/or other light-emitting diodes 130.

FIG. 5 shows an embodiment of the optical voltage converter 10, in which a plurality of light-emitting diodes 110 for generating light are arranged on a first region 101 of the carrier substrate 100 of the optical voltage converter 10. The plurality of photovoltaic chips 120 and/or the plurality of further light emitting diodes 130 are arranged on a second region 102 of the carrier substrate 100 which is different from the first region 101.

In the embodiment of the optical voltage converter 10 shown in FIG. 5, the light-emitting diodes 110 for emitting light and the photovoltaic chips 120 and/or the further light-emitting diodes 130 for converting the generated light into the output voltage Vout are thus arranged on different areas of the carrier substrate 100. Photovoltaic chips 120 or light-emitting diodes 130 that are arranged further away from the light-emitting diodes 110 receive less light than those photovoltaic chips 120 or light-emitting diodes 130 that are arranged closer to the light-emitting diodes 110. At low intensities of the light emitted by the light-emitting diodes 110, only the photovoltaic chips 120 and/or the light-emitting diodes 130 arranged close to the region 101 receive the emitted light and contribute to converting the light into the output voltage Vout. If, on the other hand, the light-emitting diodes 110 generate the light with a higher intensity, more photovoltaic chips 120 and/or light-emitting diodes 130 contribute to the voltage generation, so that in this case the level of the output voltage is increased. In the embodiment shown in FIG. 5, the level of the output voltage Vout can thus be changed as a function of the current flowing through the light-emitting diodes 110 and thus as a function of the intensity of the light generated.

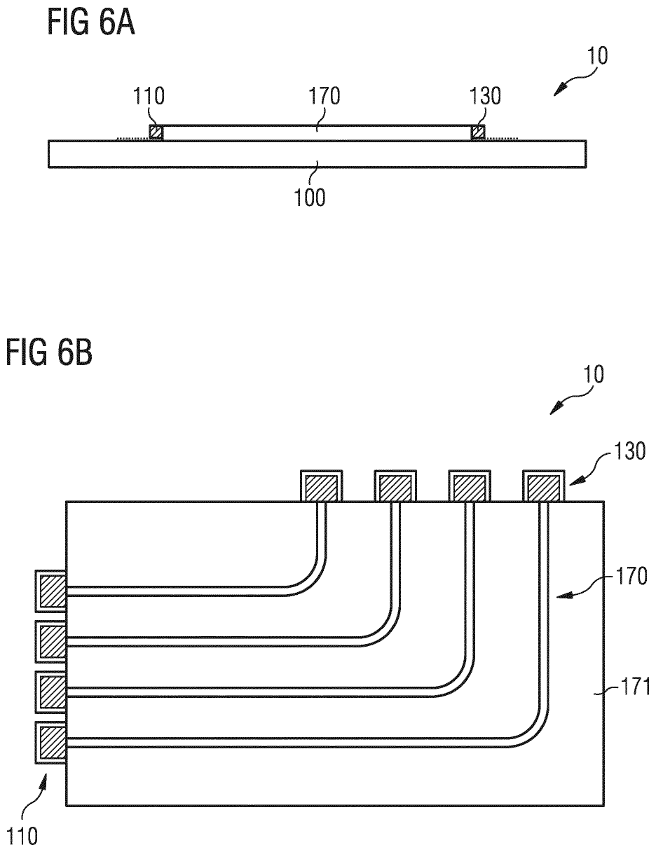

FIGS. 6A and 6B show a further embodiment of the optical voltage converter 10 for the component with photonic integrated circuit. FIG. 6A shows a transverse view, while FIG. 6B shows a top view on the optical voltage converter 10. The optical voltage converter 10 comprises at least one optical waveguide 170, which is arranged between at least one light-emitting diode 110 for generating light and at least one further light-emitting diode 130 for converting the generated light into the output voltage. Instead of the light-emitting diodes 130, photovoltaic chips for receiving the light can also be contacted with the optical waveguides 170 at an end face of the substrate 171. The optical waveguides 170 may, for example, be arranged in a substrate 171 made of PMMA, glass or another material.

As shown in FIGS. 6A and 6B, the optical waveguides 110 arranged in parallel with each other may be arranged on one side of the substrate 170 and the further light-emitting diodes 130 connected in series with each other may be arranged on another side of the substrate. Those sides of the light-emitting diodes 110, 130 that are not in contact with an end face of the substrate 171 can be metallized. As a result, the light-emitting diodes 110 emit light only on that side which faces the optical waveguide 170, and the light-emitting diodes 130 receive the light only on that side which faces the optical waveguide 170 or is in contact with the optical waveguide 170.

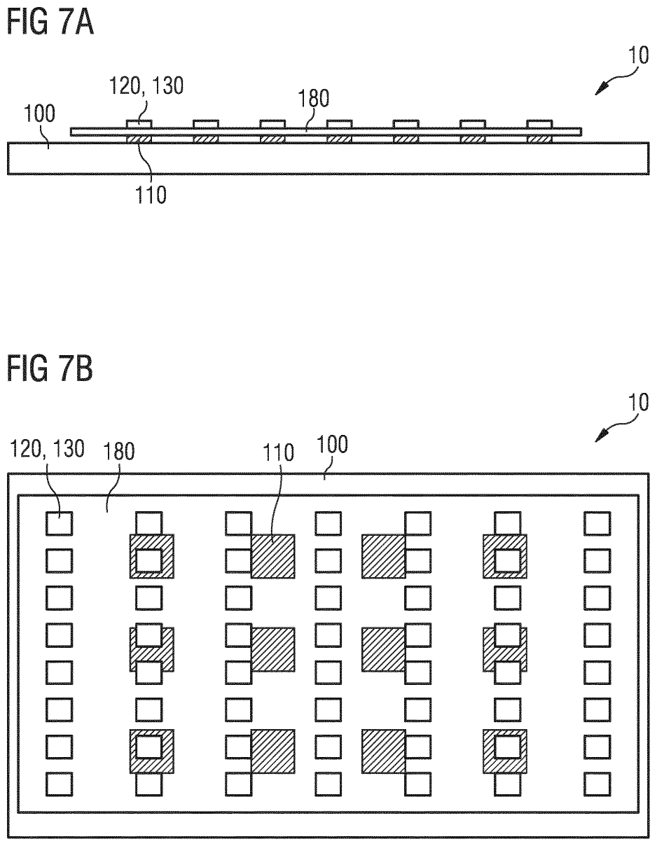

FIGS. 7A and 7B show a further embodiment of the optical voltage converter 10 in a cross-sectional view (FIG. 7A) and a top view (FIG. 7B). The light-emitting diodes 110 for generating light are arranged on the carrier substrate 100. In the embodiment shown in FIGS. 7A and 7B, the optical voltage converter 10 has a light-transparent intermediate substrate 180, which is arranged between the light-emitting diodes 110 and the photovoltaic chips 120 and/or the further light-emitting diodes 130.

The light-transparent intermediate substrate 180 can, for example, have a material made of sapphire or glass, on the upper side of which, in particular, photovoltaic chips 120 are arranged. Furthermore, the light-emitting diodes 130 can be embodied as volume-emitting light-emitting diodes. In this case, the light-transparent intermediate substrate 180 may comprise a material made of glass, for example.

On the one hand, the intermediate substrate 180 serves as a carrier substrate for the photovoltaic chips 120 or the further light-emitting diodes 130 for converting the generated light into an output voltage. On the other hand, the light emitted by the light-emitting diodes 110 is scattered in the light-transparent intermediate substrate 180, so that the light-emitting diodes 110 together with the light-transparent intermediate substrate 180 form a planar light source.

As shown in FIG. 7B, the positions of the light-generating light-emitting diodes 110 in the plan view do not have to coincide with the positions of the photovoltaic chips 120 or the positions of the further light-emitting diodes 130 on the upper side of the intermediate substrate 180, since the light generated by the light-emitting diodes 110 is scattered in the light-transparent intermediate substrate 180.

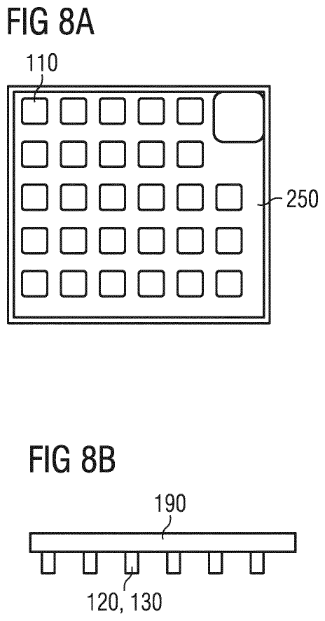

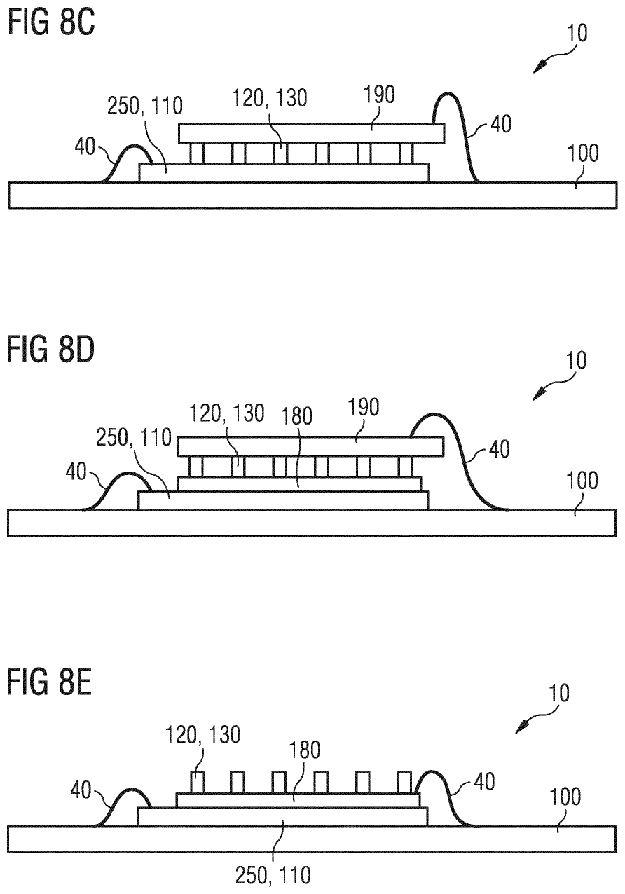

FIG. 8A shows a substrate 250 of the optical voltage converter 10, on which a plurality of light-emitting diodes 110 are arranged for generating light. The substrate 250 can be formed as a thin-film substrate. The multiple light-emitting diodes 110 therefore form a so-called thin-film LED together with the thin-film substrate 250.

FIG. 8B shows photovoltaic chips 120 or light-emitting diodes 130 for converting the light generated by the light-emitting diodes 110 into an output voltage, wherein the photovoltaic chips 120 or further light-emitting diodes 130 are arranged on a second substrate 190.

FIGS. 8C, 8D and 8E show various ways in which the photovoltaic chips 120 or the further light-emitting diodes 130 for converting the generated light into the output voltage can be arranged on the thin-film substrate 250 with the light-emitting diodes 110.

According to the embodiment shown in FIG. 8C, the photovoltaic chips 120 and/or the further light-emitting diodes 130 for converting the generated light into the output voltage are arranged directly on the light-emitting diodes 110 and the substrate 250. In the case of a thin-film substrate 250, the photovoltaic chips 120 and/or the further light-emitting diodes 130 are arranged directly on the thin-film LED. The electrical connection to the carrier substrate 100 of the component can be made via bonding wires 40, which are arranged between the substrate 250 and the carrier substrate 100 or between the second substrate 190 and the carrier substrate 100.

In the embodiment shown in FIG. 8D, the optical voltage converter 10 comprises a light-transparent intermediate substrate 180 on which the module comprising the second substrate 190 and the photovoltaic chips 120 or the further light-emitting diodes 130 is arranged. The light-transparent intermediate substrate 180 is arranged on the substrate 250 with the light-emitting diodes 110. In the case of a thin-film substrate 250, the light-transparent intermediate substrate 180 is arranged on the thin-film LED comprising the thin-film substrate 250 and the optical waveguides 110. As in FIG. 8A, the two substrates 190 and 250 are connected to the carrier substrate 100 via bonding wires 40.

According to the embodiment shown in FIG. 8E, the optical voltage converter 10 comprises a light-transparent intermediate substrate 180 that is arranged between the arrangement of the plurality of light-emitting diodes 110 and the substrate 250 and the arrangement of the plurality of photovoltaic chips 120 or the plurality of the further light-emitting diodes 130. In the case of a thin-film substrate 250, the intermediate substrate 180 is arranged between the thin-film LED and the multiple photovoltaic chips 120 or further light-emitting diodes 130. In the embodiment shown in FIG. 8E, the photovoltaic chips 120 or the further light-emitting diodes 130 are arranged directly on the intermediate substrate 180 without using a second substrate 190. The intermediate substrate 180 therefore serves as a carrier substrate for the photovoltaic chips 120 or the further light-emitting diodes 130. The intermediate substrate 180 and the substrate 250 are connected to the carrier substrate 100 via bonding wires 40.

In the embodiments shown in FIGS. 8d and 8e, the intermediate substrate 180 serves as an optical waveguide for transmitting light between the light-radiating light-emitting diodes 110 and the light-receiving photovoltaic chips 120 and/or the further light-emitting diodes 130.

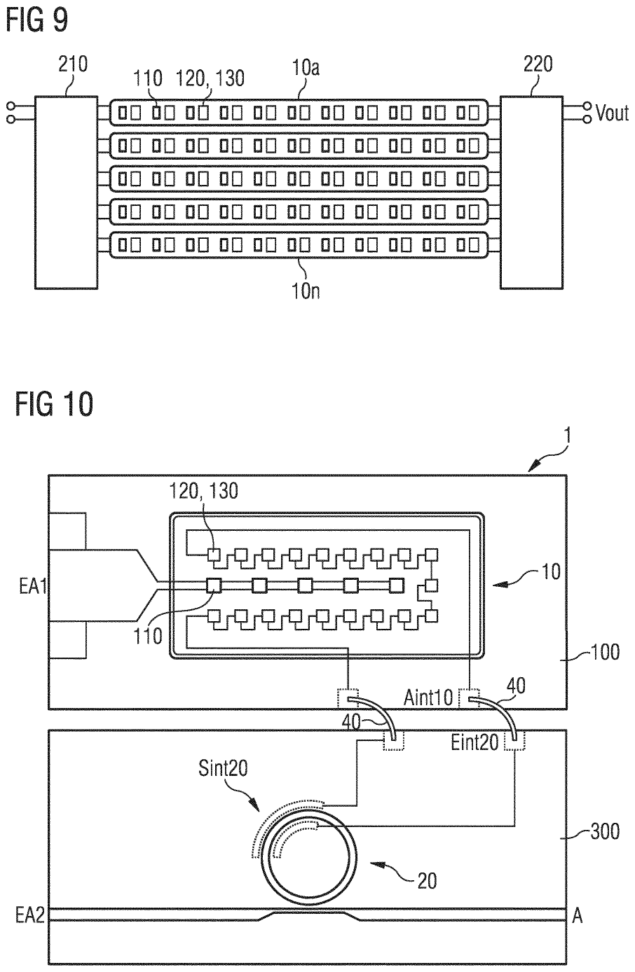

FIG. 9 shows an arrangement for generating the output voltage Vout comprising a plurality of optical voltage converters 10a, . . . , 10n and at least one control logic circuit 210, 220. The control logic circuit 210, 220 is adapted to select at least one of the plurality of optical voltage converters 10a, . . . , 10n to generate the output voltage Vout. In the example shown in FIG. 9, the control logic circuit 210 forms an input control unit and the control logic circuit 220 forms an output control unit in order to generate output voltages or output currents with different levels by selecting one or more voltage converters 10a, . . . , 10n.

As shown in FIG. 1, the components of the optical voltage converter 10, for example the at least one light emitting diode 110 and the at least one photovoltaic chip 120 or the at least one further light emitting diode 130, and the components of the photonic integrated circuit 20, for example the optical waveguide 310 and the ring oscillator 320, can be arranged on the carrier substrate 100 of the component 1. In this embodiment, the optical voltage converter 10 and the photonic integrated circuit 20 are thus arranged in the housing 30 on a common carrier substrate.

FIG. 10 shows a further embodiment of the component 1 with a second carrier substrate 300, which is arranged in the housing 30 spatially separated from the carrier substrate 100. The components of the optical voltage converter 10 are arranged on the carrier substrate 100, while the components of the photonic integrated circuit 20 are arranged on the second carrier substrate 300.

In the embodiment shown in FIG. 10, the photonic integrated circuit 20 comprises an internal input terminal Eint20 for applying the output voltage Vout. The photonic integrated circuit 20 comprises an internal control terminal Sint20, via which the output voltage Vout is applied to the components of the photonic integrated circuit. The internal input terminal Eint20 and the internal control terminal Sint20 of the photonic integrated circuit 20 are arranged on the second carrier substrate 300. The internal output terminal Aint10 of the optical voltage converter 10 is arranged on the carrier substrate 100. The internal output terminal Aint10 of the optical voltage converter 10 and the internal input terminal Eint20 of the photonic integrated circuit 20 may, for example, be connected to each other via a bonding wire 40.

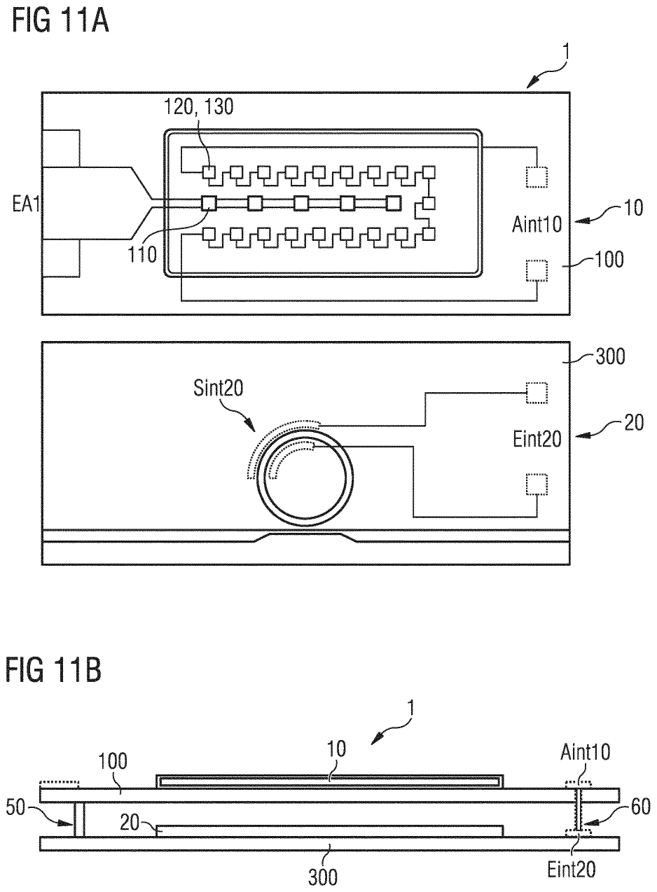

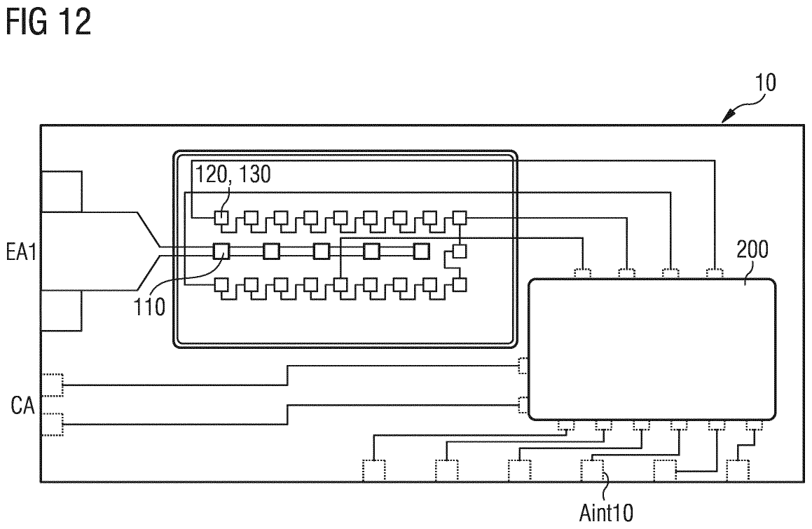

FIGS. 11A and 11B show a further embodiment of the component 1, in which the carrier substrate 100 of the optical voltage converter 10 and the second carrier substrate 300 of the photonic integrated circuit 20 are spatially separated from each other in the housing 30. The internal input terminal Eint20 and the internal control terminal Sint20 of the photonic integrated circuit 20 are arranged on the second carrier substrate 300. The internal output terminal Aint10 of the optical voltage converter 10 is arranged on the carrier substrate 100. As shown in the cross-sectional view of FIG. 11B, the carrier substrate 100 of the optical voltage converter 10 and the second carrier substrate 300 of the photonic integrated circuit 20 may be accommodated in the housing 30 in a stacked arrangement.

Spacers 50 can be arranged between the two carrier substrates 100 and 300. To apply the output voltage Vout to the internal input terminal Eint20 of the photonic integrated circuit, electrical connections/contacts 60 can be arranged between the internal output terminal Aint10 of the optical voltage converter 10 and the internal input terminal Eint20 of the photonic integrated circuit 20. The connections/contacts 60 may be formed as vias or metal vias and may serve as further spacers. By using a stacked arrangement of the two carrier substrates 100 and 300, the space required for the external contacts can be reduced.

FIG. 12 shows an embodiment of the optical voltage converter 10 with a control circuit 200 and a control terminal CA for applying a control signal. The control circuit 200 is connected on the input side to the series circuit comprising the photovoltaic chips 120 and/or the light-emitting diodes 130 for converting the light generated by the light-emitting diodes 110 into an output voltage.

As shown in FIG. 12, the control circuit 200 can be connected on the input side to different taps of the series circuit comprising the photovoltaic chips 120 and/or the light-emitting diodes 130, so that different levels of the output voltage Vout are present on the input side of the control circuit 200. The control circuit 200 is designed to provide different levels of the output voltage Vout at the internal output connection Aint10 depending on the control signal at the control terminal CA.

The control circuit 200 can be arranged as an unpackaged chip on the carrier substrate 100. Different components of the photonic integrated circuit, for example different modulators that require different control/operating voltages, can be connected to the output terminal Aint10.

The embodiment for the optical voltage converter 10 shown in FIG. 12 is not limited to the electronic control circuit 200. In principle, various electronic components can be integrated into the carrier substrate 100 in order to provide the flexibility and additional functionality of the optical voltage converter.

The photonic integrated circuit device is not limited by the description to the embodiments described therein. Rather, the disclosed subject matter includes any new feature as well as any combination of features, which includes in particular any combination of features in the claims, even if that feature or combination itself is not explicitly stated in the claims or embodiments.

The patent application claims the priority of the German patent application 10 2022 111 949.1, the content of which is hereby incorporated by reference into the description.

### List of reference symbols

1 Component with photonic integrated circuit
10 optical voltage converter
20 photonic integrated circuit
30 housing
40 bond wire
50 spacer
60 electrical connection
100 carrier substrate
110 light-emitting diode for light generation
120 photovoltaic chip
130 light-emitting diode
140 reflective layer
150 intermediate layer
160 wavelength-converting particles
170 fiber optic cable
180 light-transparent intermediate substrate
190 substrate
200 control circuit
210, 220 control logic circuit
230 dam
240 metallization
250 substrate
300 carrier substrate
310 fiber optic cable
320 ring oscillator
Aint internal output terminal
Eint internal input terminal
Sint internal control terminal
Vout output voltage

1. A component with photonic integrated circuit, comprising:
an input terminal with a first input contact and a second input contact for applying an input voltage between the first input contact and the second input contact,
an optical voltage converter for providing an output voltage at an internal output terminal of the component for operating the photonic integrated circuit,
wherein the optical voltage converter is configured such that the output voltage provided by the optical voltage converter is higher than the input voltage.

2. The component according to claim 1,
wherein the optical voltage converter and the photonic integrated circuit are arranged in a housing of the component.

3. The component according to claim 1, comprising:
a carrier substrate,
wherein the optical voltage converter comprises at least one light-emitting diode for generating light and at least one photovoltaic chip and/or at least one further light-emitting diode for converting the light generated by the at least one light-emitting diode into the output voltage,
wherein the at least one light-emitting diode and the at least one photovoltaic chip and/or the at least one further light-emitting diode are arranged on the carrier substrate.

4. The component according to claim 3,
wherein the optical voltage converter comprises a plurality of the at least one light-emitting diode and a plurality of the at least one photovoltaic chip and/or a plurality of the at least one further light-emitting diode,
where the plurality of light-emitting diodes are connected in parallel between the first input contact and the second input contact,
wherein the plurality of photovoltaic chips and/or the plurality of further light-emitting diodes are arranged in a series connection between a first internal output contact and a second internal output contact of the internal output terminal.

5. The component according to claim 4,
wherein the plurality of light-emitting diodes are arranged on a first region of the carrier substrate,
wherein the plurality of photovoltaic chips and/or the plurality of further light-emitting diodes are arranged on a second region of the carrier substrate which is different from the first region.

6. The component according to claim 3,
wherein the optical voltage converter comprises a reflective layer arranged over the at least one light-emitting diode and the at least one photovoltaic chip and/or the at least one further light-emitting diode,
wherein the optical voltage converter has an intermediate layer made of a light-transparent material,
wherein the intermediate layer is arranged between the substrate of the optical voltage converter and the reflective layer.

7. The component according to claim 6,
wherein the intermediate layer comprises wavelength-converting particles which are mixed into the light-transparent material of the intermediate layer.

8. The component according to claim 3,
wherein the optical voltage converter comprises at least one optical waveguide, which is arranged between the at least one light-emitting diode and the at least one photovoltaic chip and/or the at least one further light-emitting diode.

9. The component according to claim 3,
wherein the optical voltage converter comprises a light-transparent intermediate substrate, which is arranged between the at least one light-emitting diode and the at least one photovoltaic chip and/or the at least one further light-emitting diode.

10. The component according to claim 4,
wherein the optical voltage converter comprises a substrate on which the plurality of light emitting diodes are arranged, and a second substrate on which the plurality of photovoltaic chips and/or the plurality of further light emitting diodes are arranged,
wherein the substrate is formed as a thin-film substrate,
wherein the plurality of photovoltaic chips and/or the plurality of further light-emitting diodes are arranged directly on the plurality of light-emitting diodes.

11. The component according to claim 4
wherein the optical voltage converter comprises a substrate on which the plurality of light-emitting diodes are arranged, and a second substrate on which the plurality of photovoltaic chips and/or the plurality of further light-emitting diodes are arranged,
wherein the substrate is formed as a thin-film substrate,
wherein the optical voltage converter comprises a light-transparent intermediate substrate arranged between the plurality of light-emitting diodes and the plurality of photovoltaic chips and/or the plurality of further light-emitting diodes.

12. The component according to claim 4,
wherein the optical voltage converter comprises a substrate on which the plurality of light emitting diodes are arranged,
wherein the substrate is formed as a thin-film substrate,
wherein the optical voltage converter comprises a light-transparent intermediate substrate arranged between the plurality of light-emitting diodes and the plurality of photovoltaic chips and/or the plurality of further light-emitting diodes.

13. The component according to claim 1, comprising:
a control terminal for applying a control signal,
wherein the optical voltage converter comprises a control circuit,
wherein the control circuit is configured to provide different levels of the output voltage at the internal output terminal depending on the control signal.

14. The component according to claim 1, comprising:
a plurality of the optical voltage converter,
at least one control logic circuit,
wherein the control logic circuit is configured to select at least one of the plurality of optical voltage converters to generate the output voltage.

15. The component according to claim 1,
wherein components of the photonic integrated circuit are arranged on the carrier substrate.

16. The component according to claim 1, comprising:
a second carrier substrate
wherein components of the photonic integrated circuit are arranged on the second carrier substrate
wherein the second carrier substrate is arranged in the housing spatially separated from the carrier substrate.

17. The component according to claim 16,
wherein the photonic integrated circuit has an internal input terminal for applying the output voltage,
where the internal output terminal of the optical voltage converter and the internal input terminal of the photonic integrated circuit are connected to each other via a bonding wire.

18. The component according to claim 16,
wherein the carrier substrate and the second carrier substrate are accommodated in the housing in a stacked arrangement.
